(19) United States
(12) Patent Application Publication
(10) Pub. No.: US 2007/0018666 A1
(43) Pub. Date: Jan. 25, 2007

(54) Spring contact pin for an IC chip tester

(76) Inventors: Nasser Barabi, Lafayette, CA (US); Oksana Kryachek, San Francisco, CA (US); Chee-Wah Ho, Fremont, CA (US)

Correspondence Address: BEESON SKINNER BEVERLY, LLP, ONE KAISER PLAZA, SUITE 750, OAKLAND, CA, 94612, US

(21) Appl. No.: 11/490,869

(22) Filed: Jul. 20, 2006

Related U.S. Application Data
(60) Provisional application No. 60/702,009, filed on Jul. 22, 2005.

(51) Int. Cl. G01R 31/02

(52) U.S. Cl. 324/761

(57) ABSTRACT

A spring contact for IC chip test sockets, contactors, and the like is comprised of a barrel casing and two spring-loaded plungers, and an inward indentation formed at one end of the barrel casing, which pushes into the base end of one of the plungers for reducing the contact resistance between the one plunger and the barrel casing. Preferably, the inward indentation of the spring casing is formed by crimping the end of the spring casing.

### CROSS-REFERENCE TO RELATED APPLICATIONS

This application claims the benefit of U.S. Provisional Application Ser. No. 60/702,009 filed Jul. 22, 2005.

### BACKGROUND OF THE INVENTION

The present invention generally relates to test sockets and contactors for testing and burning-in integrated circuit (IC) devices, and more particularly to spring contact pins, sometimes referred to as pogo pins, used in test sockets and contactors to make circuit connections between an IC device and a test or burn-in circuit board.

As their capabilities increase, the input/output (I/O) densities of IC chips have increased, leading to a shift from chips with physical leads to leadless devices. For example, surface mounted IC chips with ball grid array (BGA) packages and micro-BGA packages are now in widespread use because BGA's allow for more densely packed contacts—small solder balls—having relatively small contact dimensions. The small contact dimensions create challenges in the test and burn-in of leadless devices. To facilitate testing and burn-in, test sockets and contactors have been designed for holding the BGA chip packages and connecting and disconnecting chip's I/O contacts to a printed circuit (PC) test board, such as used in an automated chip tester. Such socket devices commonly use tiny double-ended pogo pins, whose length is measured in millimeters, for achieving this electrical interconnection. Double-ended pogo-pins, which have a conductive plunger at both ends of a conductive spring barrel and which are provided in densely packed arrays in a thin contact wall that is interposed between the device under test and the test circuit, are intended to provide an efficient electrical path between chip and test circuit. Because the electrical path passes through the plungers and the conductive sidewalls of the pogo pin's spring barrel, the internal resistance of the pins tends to be dominated by the contact resistance created at the junction of the plungers and the barrel sidewalls. This contact resistance is relatively high and occurs at two points in the conductive path through the pins, namely, at the plunger-to-barrel contact for each plunger. The resulting increase in the internal resistance of the pogo pins is detrimental to the pogo pins' overall electrical performance, and the performance of the test socket or contactor in which the pogo pins are used.

In an effort to reduce the undesirable contact resistance in double-ended pogo pins, a single-ended pogo pin has been devised, which has a barrel housing that tapers to a point at one end and a spring-loaded plunger at the other end. While this design eliminates the relatively high contact resistance associated with one of the plungers, it has significant disadvantages. First, it is relatively difficult to manufacture. Also, it is often desirable to make pogo pins having contact tips fabricated of a different material than the material used for the spring barrel casing. For example, it may be desirable to make both tips of a harder conductive material than the housing material. Where one of the contact tips of the pogo pin is the end of the barrel casing itself, this will not be feasible.

Therefore, a need exists for a spring contact pin that has reduced internal resistance as compared to conventional double-ended pogo pins, but that do not have the disadvantages of single-ended pogo pins of the type described above. The need also exists for an improved spring contact pin that can be readily manufactured, and that minimizes the risk that foreign particles will find their way into the spring cavity of the pin during manufacture.

### SUMMARY OF THE INVENTION

Briefly, the present invention is an improved spring contact pin for an IC test device, such as a test socket or contactor, which has a lower internal resistance compared to conventional double-ended pogo pins, but which provide advantages over the single-ended pogo pin design mentioned above. The invention is also directed to a method of manufacturing a spring contact pin, which reduces the internal resistance of the contact.

The spring contact pin of the invention is comprised of a conductive spring barrel casing having a conductive longitudinal barrel sidewall, a compression spring and two conductive plungers. The plungers are contained in the spring cavity at the ends of the spring barrel with the compression spring being disposed in the spring cavity between plungers. At least one inwardly indented portion in the sidewall of the barrel casing is provided at one of the barrel ends, wherein the indented portion firmly grips the plunger so as to reduce the contact resistance between the one plunger and the barrel casing. Preferably, the indented portion in the sidewall of the barrel casing is produced by crimping the barrel casing.

The spring contact pin of the invention can be manufactured from a standard double-ended pogo pin by crimping one end of the pin's barrel casing so that it crimps into one of the plungers of the double-ended pin. Such crimping would fix the one plunger in a non-depressible position, while allowing the other plunger to be depressed in the conventional manner. As a result of the crimping, the contact resistance between the plunger and casing at the crimped end can be reduced, thereby reducing the overall internal resistance of the pogo pin. This is achieved by a relatively simple manufacturing process that will allow the plungers and the barrel casing to be made of different materials, if desired. Also, the crimping process can be achieved without exposing the internal spring cavity of the spring contact pin to the introduction of foreign materials which would be detrimental to the performance of the spring.

It is contemplated that the plungers of the spring contact pin of the invention would be made of a relatively hard conductive material such as beryllium copper. The barrel casing of the spring contact pin, on the other hand, could be made of beryllium copper or another conductive material such as brass.

While the invention contemplates crimping of the end of the barrel casing of the spring contact pin, it will be understood that it is not intended that the invention be limited to crimping as a method of producing an inward indentation in the barrel casing sidewall that grips or pushes into one of the spring contact pin's plungers for reducing contact resistance. However, crimping provides a facility for easily manufacturing the spring contact pin of the invention.

While it is also contemplated that one end of the spring contact pin of the invention will be crimped around its entire circumference to produce a uniform indentation around the circumference, other forms of crimps in the barrel casing sidewall are considered within the scope of the invention. This might include partial crimps and crimps that are non-uniform.

Therefore, it can be seen that it is a primary object of the invention to provide an improved spring contact pin for an IC test socket, contactor or the like, which has improved performance characteristics and which particularly exhibits lower internal resistance than conventional pogo pins having doubled depressible ends. It is a further object of the invention to provide an improved spring contact pin which can be produced economically. It is still a further object of the invention to provide a spring contact pin wherein the spring casing and contacting tip ends of the spring contact pin can be fabricated of different materials, if desired. Other objects of the invention will be apparent from the following specification and claims and the accompanying drawings.

### DESCRIPTION OF THE DRAWINGS

FIG. 1A is a cross-sectional view of a prior art spring contact pin of the type of which the present invention is an improvement;

FIG. 1B is a cross-sectional view thereof, showing the plunger ends of the spring contact pin depressed by the contact pads of an IC package and a PC test board;

FIG. 2 is a cross-sectional view of another prior art spring contact pin having a single depressible plunger;

FIG. 3 is a top perspective view of a spring contact pin in accordance with the invention;

FIG. 4A is a cross-sectional view thereof taken along line 4A-4A in FIG. 3, showing the depressible plunger of the spring contact pin in its fully extended position;

FIG. 4B is a cross-sectional view thereof showing the depressible plunger and fixed plunger contacting the contact pads of an IC package and a printer circuit board, and showing the one depressible plunger in its depressed position;

FIG. 5 is a graph of test results comparing the performance of a conventional spring contact pin as shown in FIGS. 1A and 1B to the spring contact pin of the invention as shown in FIGS. 3, 4A and 4B.

### DETAILED DESCRIPTION OF THE ILLUSTRATED EMBODIMENT

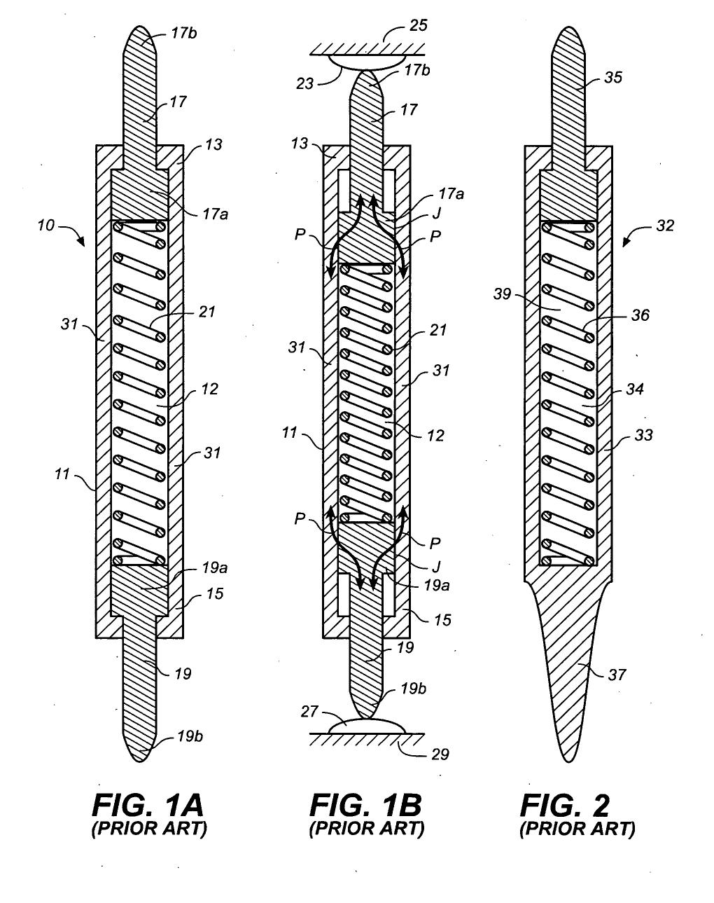

Referring now to the drawings, FIGS. 1A and 1B show a conventional spring contact pin in the form of a double-ended pogo pin 10 having a barrel casing 11, barrel ends 13, 15, and plungers 17, 19 at each of the barrel casing. Each of the plungers has a base end 17a, 19a, and a contact tip end 17b, 19b. Compression spring 21 is disposed within the spring cavity 12 of the barrel casing and engages the base ends of the plungers to force the plungers to their fully extended position. As shown in FIG. 1B, the plungers will depress against the compression spring 21 when the contact tip ends 17b, 19b contact, respectively, one of the contact pads 27 of the PC test board 29 and one of the contact pads 23 of the device under test (DUT) 25 held in a test socket or contactor (not shown).

The barrel casing and plungers of the spring contact pin shown in FIGS. 1A and 1B are fabricated of conductive materials to provide an electrical path through the spring contact pin. The electrical path is provided by the plungers 17, 19 and the sidewall 31 of the barrel casing 11. As denoted by the letter “P,” this path extends across the contact junctions “J” between the base ends of plungers 17, 19 and the barrel sidewall. The contact resistance across contact junctions “J” for both plungers is relatively high and contributes significantly to the overall internal resistance of the pogo pin. For example, the overall internal resistance of a double-ended pogo pin as graphically illustrated in FIGS. 1A and 1B will typically be in the range of 17.5 milliohms, with the contact resistance of junction “J” at each plunger contributing approximately 7 milliohms to this overall resistance, or a total of 14 milliohms. This internal resistance is detrimental to the performance of test devices in which the spring contact pins are used and it is generally desirable to reduce this internal resistance as much as possible.

FIG. 2 illustrates a prior art approach that has been taken to decrease the internal resistance in a spring contact pin. In FIG. 2, the barrel casing 33 of spring contact pin 32, instead of having two depressible plungers, has an integrally formed contact tip 37 at one end of the casing and a depressible plunger 35 at the other end. In this approach, the number of contact junctions having relatively high contact resistance is cut in half, therefore substantially reducing the overall internal resistance of the spring contact pin. However, as above mentioned, the spring contact pin illustrated in FIG. 2 is relatively difficult to manufacture. Also, it can be seen that the contact tip 37 formed at one end of the spring casing will be of the same material as the casing. Thus, it would be very difficult to fabricate a spring contact pin with both contact tips being of a different material than the spring housing.

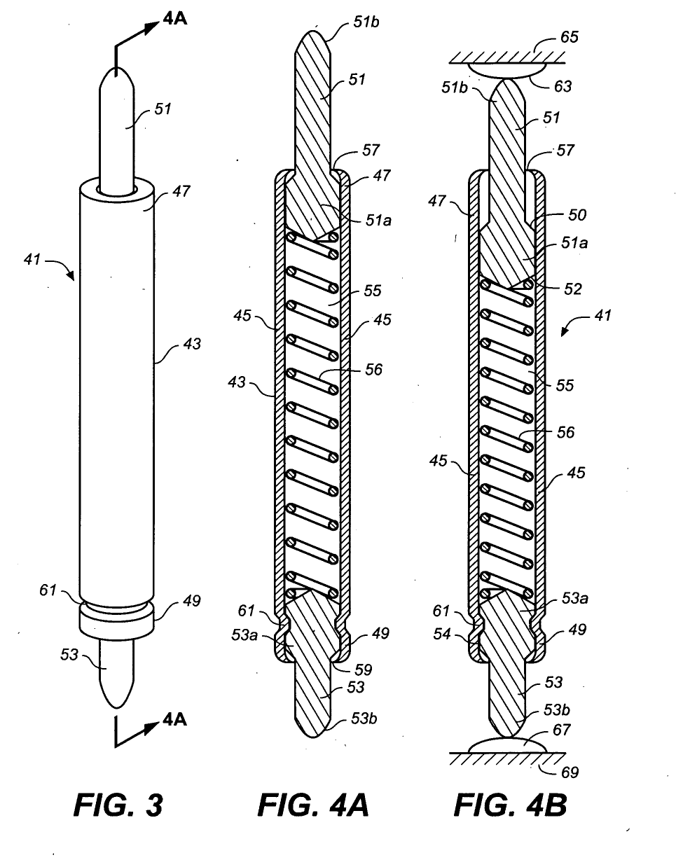

The improved spring contact pin of the invention illustrated in FIGS. 3, 4A and 4B, and generally denoted by the numeral 41, is comprised of an elongated conductive barrel casing 43 having a longitudinal barrel sidewall 45, a first barrel end 47, and a second barrel end 49. The barrel casing holds a first conductive plunger 51 and a second conductive plunger. 53, each of which has an enlarged base end 51a, 53a and a contact tip end 51b, 53b. The base end 51a of plunger 51 is seen to be contained within the barrel casing's spring cavity 55 at the casing's first end 47, while the base end 53a is contained within the casing's spring cavity at the casing's second end 49. (Each base end suitably has a diameter that is slightly smaller than the inside diameter of the spring cavity 55, and also suitably has an angled front shoulder 50, and a conical back wall 52.) The contact tip ends of the respective plungers extend from the plungers' base ends through pin openings 57, 59 in the ends of the barrel casing. The dimensions of the base end of the plungers are sized in accordance with the internal dimensions of the spring cavity, and so that the first plunger can slide within this cavity. A compression spring 56 is disposed within the spring cavity 55 between the first and second plungers and forces the plungers to their full extended position.

In the spring contact pin of the invention, only the first conductive plunger 51 can depress against the compression spring 56 in the manner of a conventional contact spring. To reduce the contact resistance between the second plunger 53 and the barrel casing 43, the barrel's second end 49 is provided with an inward indentation which forces at least a portion of the sidewall into the base end of the second plunger. This indentation is preferably formed by crimping the second end of the barrel casing by a suitable crimping tool (not shown). In the illustrated embodiment, the crimp formed in the sidewalls of the barrel casing extends around the entire perimeter of the barrel casing, forcing the sidewall at the crimp into the plunger base end over 360 degrees of the base end. The electrical path through the barrel casing and second plunger now passes through a junction “J” where the metal of the casing's sidewall is pressed into the sidewall 54 of the plunger base 49. Testing has shown that the overall internal resistance of the contact pin crimped in this fashion is substantially reduced over a contact pin where the sidewall is not crimped.

Referring to FIG. 4B, it can be seen that, when the spring contact pin of the invention is operatively positioned to provide a connection between a contact pad 63 of an IC package and an opposing contact pad 67 of a test circuit 69, only one of the plungers, namely plunger 51, is depressed, while the other crimped plunger 53 remains fixed in the crimped end of barrel casing 45. Because the compression of the spring contact pin is taken up entirely by the first plunger 51, this plunger will experience a greater travel than if the compression were taken up by both plungers. Because of this, plunger 51 preferably has a greater length than the crimped plunger 53. It is understood, however, that the invention is not limited to plungers having different lengths, and that it is possible to provide a spring contact pin in accordance with the invention having plungers of the same length, or even having a plunger at the crimped end of the barrel casing that is longer than the depressible plunger.

As above-mentioned, the barrel casing and plungers of spring contact pin 41 are made of conductive materials. One of the benefits of the invention is that the plungers and the barrel casing can be made of different materials. The plungers are suitably made of hardened connective materials, such as hardened beryllium copper, steel, bronze, gold or a silver alloy. The barrel casing is suitably fabricated of brass (which can be readily crimped), but could be made of other materials, including the same material as the plungers, for example, beryllium copper.

Spring contact pin 41 has the further benefit that it can be made from a conventional double-ended pogo-pin, with the only additional manufacturing step being the crimping of the second end of the barrel casing to force the sidewall of the barrel casing into the second plunger. While it is contemplated that the crimping would occur when the second plunger 53 is in its full extended position as shown in FIG. 4B, it is within the scope of the invention to crimp the barrel casing end when plunger 53 is depressed. In this case, the barrel casing would be crimped further up the end of the barrel casing, so as to engage the plunger's base end 53a.

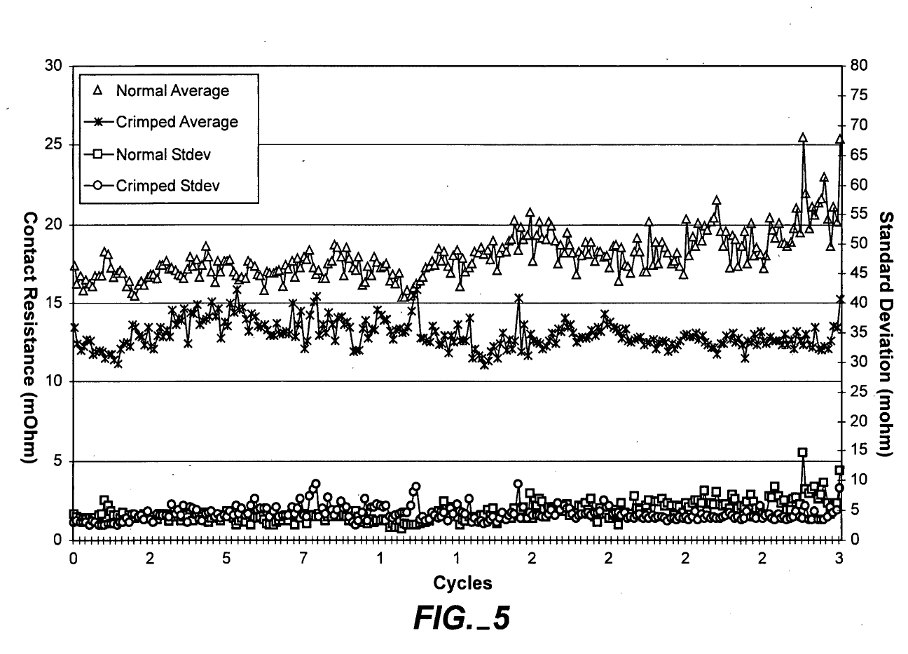

A comparison between the electrical performance of a conventional spring contact pin of the type illustrated in FIGS. 1A and 1B and the crimped spring contact pin of the invention is illustrated in FIG. 5, which shows cycling test results for the two spring contact pin designs. The left vertical axis of the graph in FIG. 5 shows contact resistance in milliohms (each point on the graph for contact resistance represents an average measurement), and the horizontal axis represents a cycling of the pogo over zero to 300,000 cycles. The right vertical axis shows standard deviations for these measurements. As shown in FIG. 5, tests on the crimped version versus the normal non-crimped spring contact pin shows a significant decrease in overall contact resistance throughout the cycling of the contacts. It is noted that the test results reveal that the comparative difference in contact resistance between the two spring contact pins actually increases over the life cycle of the spring contact pins.

Therefore, it can be seen that the present invention provides a new spring contact pin and method of manufacturing a spring contact pin for IC chip test sockets and contactors that improve the performance of the pin without any significant increase in the cost or complexity of manufacture of the contact. While the present invention has been described in considerable detail in the foregoing specification, it shall be understood that it is not intended that the invention be limited to such detail, except as necessitated by the following claims.

What we claim is:

1. An improved spring contact pin for an IC chip tester comprising
a conductive spring barrel casing having a conductive longitudinal barrel sidewall, a first barrel end and a second barrel end, and a plunger tip opening in each of said barrel ends, said spring barrel casing forming a spring cavity having an inside dimension,
a first conductive plunger having a base end and a contact tip end, the base end of said first plunger being slidably contained within the spring cavity of said barrel casing at the first barrel end thereof and providing an electrical contact with the conductive spring barrel casing which is characterized by a contact resistance, and the contact tip end of said first plunger extending from said base end through the plunger tip opening at the first barrel end of said, barrel casing,
a second conductive plunger having a base end and a contact tip end, the base end of said second plunger being contained within the spring cavity of said barrel casing at the second end thereof and being sized in correspondence with the inside dimension of the spring cavity of said barrel casing, and the contact tip end of said second plunger extending from said base end through the plunger tip opening at the second end of said barrel casing,
a compression spring disposed in the spring cavity of said barrel casing between the base ends of said first and second plunger so that at least said first plunger is depressible against said compression spring, and
at least one inwardly indented portion in the sidewall of said barrel casing at the second end thereof, which presses into the base end of said second conductive plunger so as to reduce the contact resistance between said second plunger and said barrel casing.

2. The improved spring contact pin of claim 1 wherein the inwardly indented portion in the sidewall of said barrel casing is formed by crimping.

3. The improved spring contact pin of claim 1 wherein the inwardly indented portion in the sidewall of said barrel casing extends concentrically around said sidewall at the second end of said barrel casing.

4. The improved spring contact pin of claim 3 wherein the inwardly indented portion in the sidewall of said barrel casing is formed by crimping.

5. The improved spring contact pin of claim 1 wherein said inwardly indented portion in the sidewall of said barrel casing fixes said second plunger in a non-depressible position at the second end of the barrel casing, wherein the first conductive plunger is depressible and the second conductive plunger is non-depressible.

6. The improved spring contact pin of claim 1 wherein the base ends of said first and second plungers are enlarged in relation to the contact tip ends thereof.

7. The improved spring contact pin of claim 1 wherein the spring barrel casing, and the first and second conductive plungers are fabricated of different conductive materials.

8. The improved spring contact pin of claim 7 wherein the first and second conductive plungers are fabricated of hardened conductive material.

9. The improved spring contact pin of claim 1 wherein the spring barrel casing is fabricated of brass, and the first and second conductive plungers are fabricated of hardened beryllium copper.

10. The improved spring contact pin of claim 1 wherein the contact tip end of the first conductive plunger has a longer length than the contact tip end of said second conductive plunger.

11. An improved spring contact pin for an IC chip tester comprising
a conductive spring barrel casing having a conductive longitudinal barrel sidewall, a first barrel end and a second barrel end, and a plunger tip opening in each of said barrel ends, said spring barrel casing forming a spring cavity,
a first conductive plunger having an enlarged base end and a contact tip end, the base end thereof being slidably contained within the spring cavity of said barrel casing at the first barrel end thereof and providing an electrical contact with the conductive spring barrel casing which is characterized by a contact resistance, and the contact tip end thereof extending from said base end through the plunger tip opening at the first barrel end of said barrel casing,
a second conductive plunger having an enlarged base end and a contact tip end, the base end thereof being contained within the spring cavity of said barrel casing at the second end thereof, and the contact tip end thereof extending from said base end through the plunger tip opening at the second end of said barrel casing, and
a compression spring disposed in the spring cavity of said barrel casing between the enlarged base ends of said first and second plunger so as to urge said plungers toward the ends of the barrel casing and so that the first plunger is depressible against said compression spring,
said spring barrel casing being crimped at its second end so as to crimp the barrel sidewall of the barrel casing into the enlarged base end of said second plunger, wherein the second plunger is crimped in a fixed non-depressible position by the crimped sidewall of said barrel casing.

12. An improved spring contact pin for an IC chip tester comprising
a conductive spring barrel casing having a spring cavity, a conductive longitudinal barrel sidewall, and barrel ends,
a conductive plunger contained in said barrel housing at each of said barrel ends and projecting from said barrel ends, and
a compression spring disposed in the spring cavity of said barrel casing between said plungers,
said spring barrel casing being crimped at one of said barrel ends so as to crimp the barrel sidewall into one of said plungers to reduce the contact resistance between said one plunger and said barrel casing, the other one of said plungers being depressible against the compression spring in the spring cavity of said barrel casing.

13. The improved spring contact pin of claim 12 wherein the crimp in the sidewall of said barrel casing extends uniformly around the circumference of the barrel casing.

14. The improved spring contact pin of claim 12 wherein the spring barrel casing and conductive plungers are fabricated of different conductive materials.

15. The improved spring contact pin of claim 12 wherein said conductive plungers are fabricated of a hardened conductive material.

16. The improved spring contact pin of claim 12 wherein the spring barrel casing is fabricated of brass, and the conductive plungers are fabricated of a hardened conductive material.

17. The improved spring contact pin of claim 12 wherein the conductive plungers are fabricated of a hardened conductive material selected from a group consisting of a beryllium copper, steel, bronze and a silver alloy.

18. The improved spring contact pin of claim 12 wherein the depressible plunger is longer than the plunger of at the crimped end of the barrel casing.

19. A method of reducing the internal resistance of a double-ended spring contact for an IC chip tester comprising
providing a spring contact having a conductive spring barrel casing and depressible conductive plungers at each end of said barrel casing, and
crimping one end of said barrel casing until the sidewall of the barrel casing is crimped into one of the spring contact's plungers for reducing the contact resistance between the crimped plunger and the barrel casing.

20. The method of claim 19 wherein the sidewall of the barrel casing is crimped around the entire circumference of the barrel casing.

21. The method of claim 19 wherein one of said plungers is shorter than the other plunger, and wherein the barrel casing is crimped at the end of the barrel casing containing the shorter plunger.

22. The method of claim 19 wherein the spring barrel casing is made of brass and the plungers are made of a hardened conductive material.

23. The method of claim 22 wherein the said plungers are fabricated of a hardened conductive material selected from a group consisting of a beryllium copper, steel, bronze and a silver alloy.
